(19) United States
(12) Patent Application Publication
(10) Pub. No.: US 2002/0179319 A1
(43) Pub. Date: Dec. 5, 2002

(54) ESD safe wireless type of component

(76) Inventor: Yuqun Zeng, Dongguan City (CN)

Correspondence Address: KENYON & KENYON, ONE BROADWAY, NEW YORK, NY, 10004, US

(21) Appl. No.: 10/087,706

(22) Filed: Feb. 28, 2002

Related U.S. Application Data
(63) Continuation of application No. 09/867,209, filed on May 29, 2001.

(51) Int. Cl. H05K 1/00

(52) U.S. Cl. 174/250

(57) ABSTRACT

The invention relates to a novel wireless type of component used for all kinds of connections to ESD sensitive devices such as a slider, pre-amp, to micro-actuator etc of a disk drive in a magnetically data-storing memory. The invention provides an effective solution for overcoming ESD damage of the ESD sensitive device due to tribo-charges or any static charges induced in a wireless type of component by applying a dissipative layer onto the top surface of the conventional wireless type of component so as to prevent from inducing charges in the process of connection of the wireless type of component to the ESD sensitive device.

### CROSS-REFERENCE TO RELATED APPLICATION

This application is a continuation of U.S. Ser. No. 09/867,209, filed on May 29, 2001, which is incorporated herein by reference.

### TECHNICAL FIELD OF THE INVENTION

The present invention generally relates to an ESD (electrostatic discharge) safe wireless type of component, and more specifically to an ESD safe wireless type of component that is applicable to all kinds of connections to sensitive device such as a slider, pre-amp, micro-actuator etc in a disk drive.

### BACKGROUND OF THE INVENTION

Electrostatic discharge (ESD) is one of the most destructive phenomena in modem industry, especially the electronics industry. Electrostatic discharge is defined in the U.S. military handbook DOD-HKPK-263 as a transfer of electrostatic charges between bodies at different potentials by direct contact or induced by an electrostatic field. Electrostatic charge can build up on non-conducive materials as the result of the capture or release of electrons. A non-conducive can capture or release an electron by rubbing or heating it, or it can become charged through contact with another previously charged object. This transfer of electrostatic charge causes destruction and damage to electronic components estimated at millions of dollars a year.

As shown in FIG. 1, a conventional wireless type of component comprises a base 1, an electrically conductive copper trace 2 provided on base 1, and an insulating layer 3 coated on copper trace 3. ESD sensitive devices such as a magnetic transducer etc are often connected to the conventional wireless type of component. In the process of connecting them, tribocharge or some kind of static charge could be induced in the conventional wireless type of component, and charge will be induced in the ESD sensitive device as well, thereby resulting in ESD damage or performance/reliability degradation of the ESD sensitive device.

### SUMMARY OF THE INVENTION

An object of the present invention is to provide an ESD safe wireless type of component that can avoid the tribo-charges or static charges so that it becomes an ESD controlled product.

An ESD safe wireless type of component in accordance with the present invention comprises a base, an electrically conductive copper trace provided on the base, and an insulating layer coated on the conductive copper trace; wherein a dissipative coating layer of polymer is applied on the top of the insulation layer.

The dissipative coating layer of the ESD safe wireless type of component in accordance with the present invention is able to isolate the insulation material from direct tribo-charge against human handling or other materials during manufacturing processes of the ESD sensitive device.

Tribo-charge of a conventional wireless type of component against the nitrite glove goes up to 10¹⁰ Ω/□ (unit square). And surface resistivity causes above 100 kV static charges. Since the dissipative coating such as Polymer coating is applied to the ESD safe wireless type of component of the present invention, the charges go down to less than 10 V. Consequently, the protection can diminish ESD rejection from 5% to 0.02%, for example in manufacturing processes of Giant Magneto-Resistive heads.

### BRIEF DESCRIPTION OF THE DRAWINGS

The foregoing and other objects, features and advantages of the present invention will be apparent from the following detailed description of the preferred embodiments of the invention, with reference to the accompanying drawings, in which:

FIG. 1 shows a cross section of a conventional wireless type of component;

FIG. 2 shows a cross section of a wireless type of component according to the present invention with a dissipative coated thereon; and

FIG. 3 shows a top view of the wireless type of component according to the present invention.

### DETAILED DESCRIPTION OF THE PREFERRED EMBODIMENT

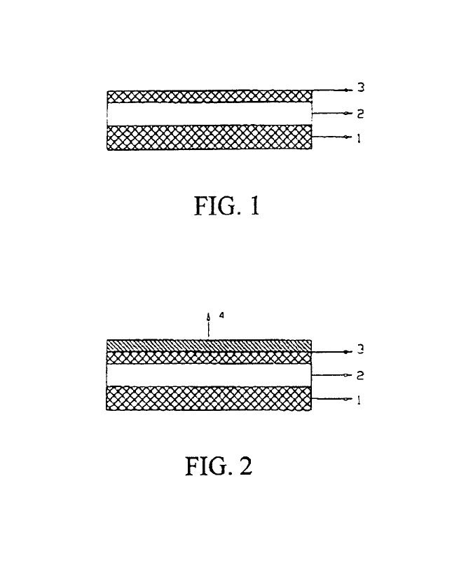

Firstly, refer to FIG. 2 which is a cross section of a wireless type of component according to the present invention. In FIG. 2, like reference numerals indicate like parts corresponding to those in FIG. 1. As shown in FIG. 2, the ESD safe wireless type of component in accordance with the present invention comprises a base 1, a copper trace 2 provided on base 1, and an insulating layer 3 coated on copper trace 2. Then, a dissipative coating layer 4 is applied on the top of insulating layer 3. Thickness of the dissipative coating layer ranges from about 5 μm to about 100 μm. Selected materials as a polymer of the dissipative coating layer need to be of compliance in the process of coating, and have surface resistivity at range of 10⁶-10¹⁰ Ω/□ (unit square). During the manufacturing process of the wireless type of component according to the present invention, an appropriate mask is employed for coating of the dissipative material with a bonding pad area exposed just after the insulating layer is coated. The connection between the insulation layer and the dissipative layer can be lamination, sputtering etc.

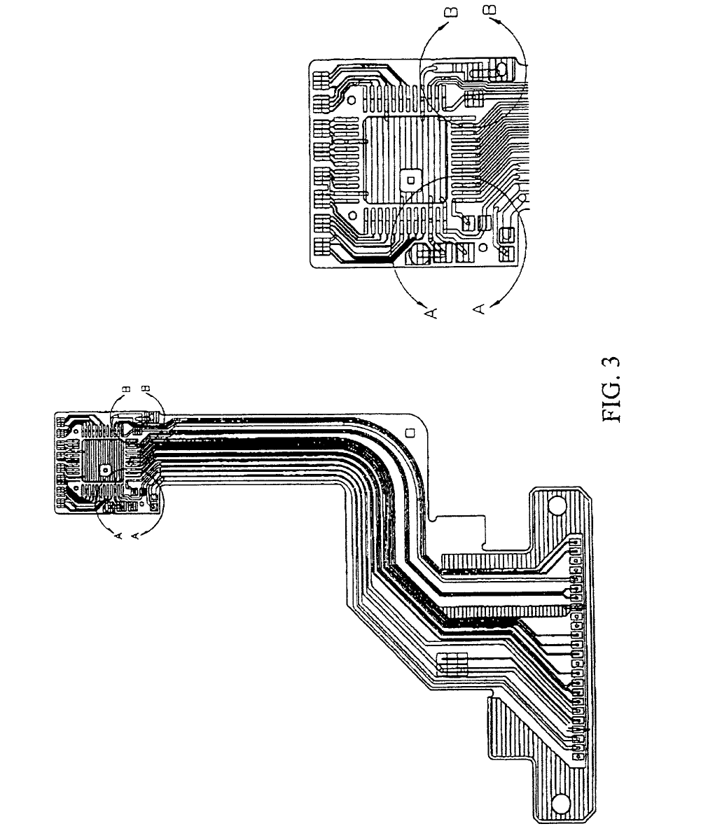

FIG. 3 is a top view of the ESD safe wireless type of component according to the present invention. A dissipative layer is applied on this ESD safe wireless type of component, but the bonding pad area is not covered by the dissipative layer.

Test results of EOS/ESD standard tribo-charges set up show that the ESD safe wireless type of component according to the present invention is capable of reducing static charge from 1000 V to below 10 V.

The present invention provides an effective solution for overcoming ESD damage of an ESD sensitive device due to tribo-charges or any static charges induced on a wireless type of component by applying a dissipative layer to the top surface of the conventional wireless type of component so as to prevent from inducing charges in the process of connection of the wireless type of component to the ESD sensitive device.

What is claimed is:

1. An ESD safe wireless type of component comprises a base (1), an electrically conductive copper trace (2) provided on base (1), and an insulating layer (3) coated on copper trace (2); wherein a dissipative coating layer (4) is applied on the top of said insulation layer (3).

2. An ESD safe wireless type of component according to claim 1, wherein the surface resistivity of said dissipative coating layer ranges about 10⁴-10¹¹ Ω/□ (unit square).

3. An ESD safe wireless type of component according to claim 1, wherein said dissipative coating layer ranges about 5-100 μm in thickness.

4. An ESD safe wireless type of component according to claim 1, wherein said wireless type of component has its bonding pad area exposed.

5. An ESD safe wireless type of component according to claim 1, wherein said dissipative coating layer is applied onto all connecting cables of ESD sensitive devices.
